(19) United States
(12) Patent Application Publication
(10) Pub. No.: US 2011/0220167 A1
(43) Pub. Date: Sep. 15, 2011

(54) Detection Device for Solar System

(76) Inventor: Yu-Tse Lin, Douliou City (TW)

(21) Appl. No.: 12/721,888

(22) Filed: Mar. 11, 2010

(51) Int. Cl. H01L 31/042

(52) U.S. Cl. 136/244

(57) ABSTRACT

A detection device for a solar system includes a plurality of solar collectors, a plurality of voltage detectors each connected to a respective one of the solar collectors, and a detection controller connected to each of the voltage detectors. Thus, the voltage detectors can detect the output voltages of the solar collectors, and the detection controller can compare the difference between the output voltages of the solar collectors so as to judge if the solar collectors are disposed at a normal operation condition, thereby facilitating maintenance of the solar collectors.

### BACKGROUND OF THE INVENTION

1. Field of the Invention

The present invention relates to a detection device and, more particularly, to a detection device for a solar system.

2. Description of the Related Art

A conventional solar system comprises a plurality of solar collectors which are connected with each other in a serial manner. The solar collectors are mounted on the top of a building or house and are arranged in an oblique manner to receive the solar energy so as to provide a generating or heating function to the building or house. However, when one of the solar collectors is worked or operated at an abnormal condition, for example, when one of the solar collectors is contaminated or inoperative, other solar collectors are easily affected by the abnormal solar collector, thereby decreasing the working efficiency of the solar system.

### BRIEF SUMMARY OF THE INVENTION

The primary objective of the present invention is to provide a detection device for a solar system to detect the operation condition of the solar system.

In accordance with the present invention, there is provided a detection device, comprising a plurality of solar collectors, a plurality of voltage detectors each connected to a respective one of the solar collectors, and a detection controller connected to each of the voltage detectors.

Each of the voltage detectors includes a voltage detection circuit connected to the respective solar collector and a wireless transmitting circuit connected to the voltage detection circuit. The detection controller includes a wireless receiving circuit connected to the wireless transmitting circuit of each of the voltage detectors and a detection control circuit connected to the wireless receiving circuit.

Each of the solar collectors has a power output terminal, and the voltage detection circuit of each of the voltage detectors is connected in parallel with the power output terminal of the respective solar collector.

The voltage detection circuit of each of the voltage detectors detects an output voltage of the respective solar collector and forms a voltage signal of the respective solar collector. The wireless transmitting circuit of each of the voltage detectors receives the voltage signal of the respective solar collector from the voltage detection circuit and transmits the voltage signal of the respective solar collector to the detection controller in a wireless manner. The wireless receiving circuit of the detection controller receives the voltage signals of the solar collectors from the wireless transmitting circuit of each of the voltage detectors. The detection control circuit of the detection controller checks the voltage signals of the solar collectors from the wireless receiving circuit to compare a difference between the voltage signals of the solar collectors so as to judge if the solar collectors are disposed at a normal generating condition.

Each of the solar collectors has a back face provided with a receiving box, and each of the voltage detectors is mounted in the receiving box of the respective solar collector.

According to the primary objective of the present invention, the voltage detectors can detect the output voltages of the solar collectors, and the detection controller can compare the difference between the output voltages of the solar collectors so as to judge if the solar collectors are disposed at a normal operation condition, thereby facilitating maintenance of the solar collectors.

According to another objective of the present invention, when the detection controller detects that the voltage of one of the solar collectors is different from that of other solar collectors, the detection controller emits a signal to inform the operator that one of the solar collectors is worked at an abnormal condition, so that the operator can clean or repair the abnormal solar collector easily and quickly.

Further benefits and advantages of the present invention will become apparent after a careful reading of the detailed description with appropriate reference to the accompanying drawings.

### BRIEF DESCRIPTION OF THE SEVERAL VIEWS OF THE DRAWING(S)

FIG. 1 is a block diagram of a detection device for a solar system in accordance with the preferred embodiment of the present invention.

FIG. 2 is a partially circuit layout of the detection device for a solar system as shown in FIG. 1.

FIG. 3 is a perspective view of a solar collector of the detection device for a solar system as shown in FIG. 1.

FIG. 4 is a bottom view the detection device for a solar system in accordance with the preferred embodiment of the present invention.

FIG. 5 is a schematic operational view of the detection device for a solar system as shown in FIG. 1 in use.

### DETAILED DESCRIPTION OF THE INVENTION

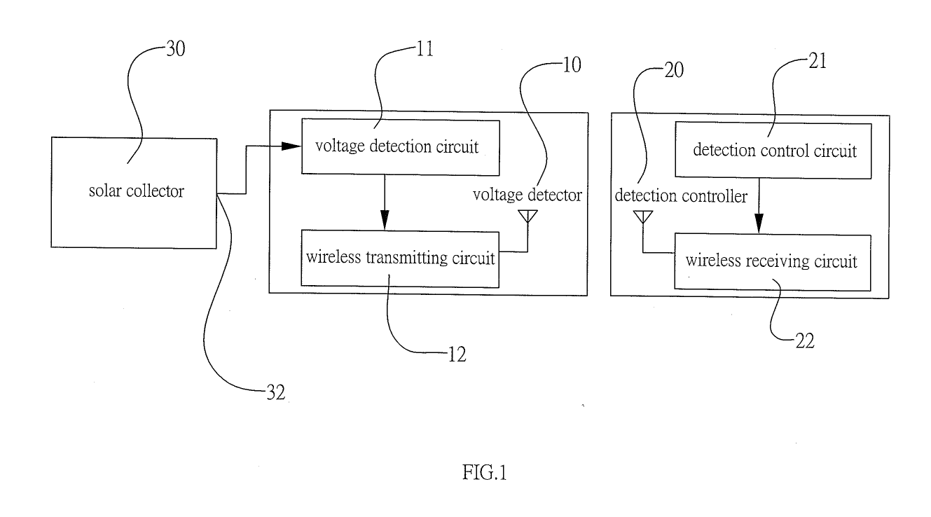

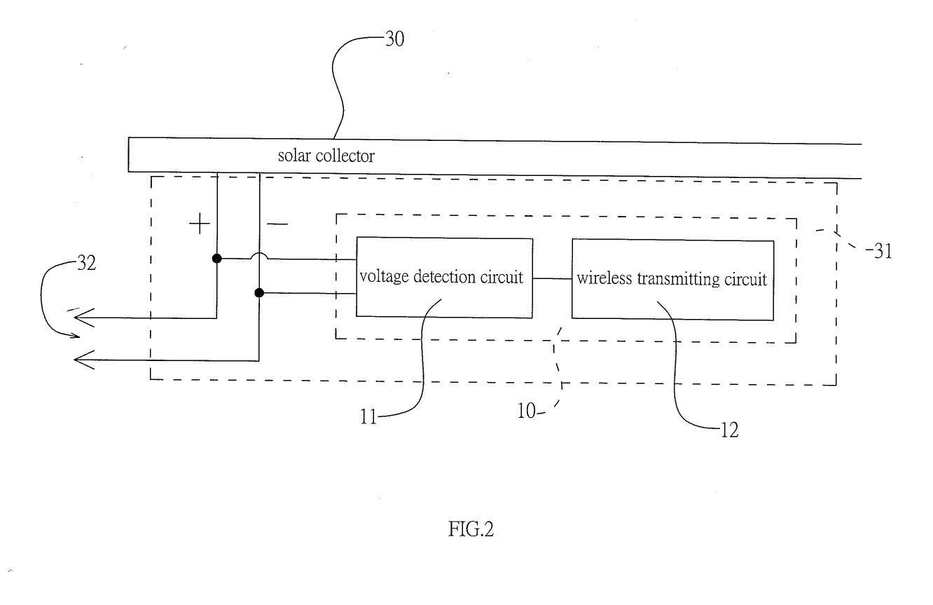

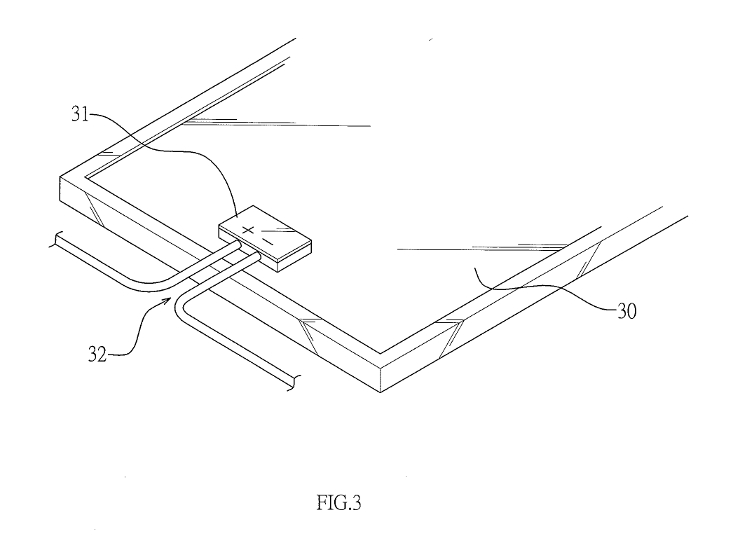

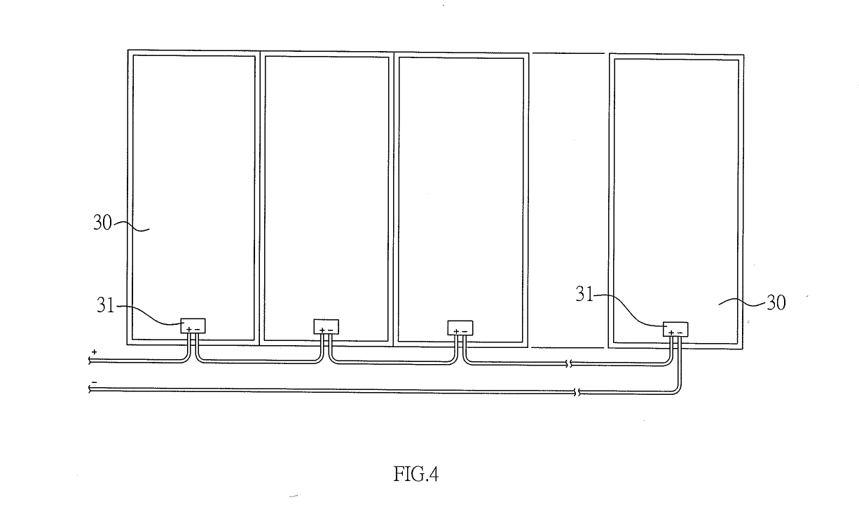

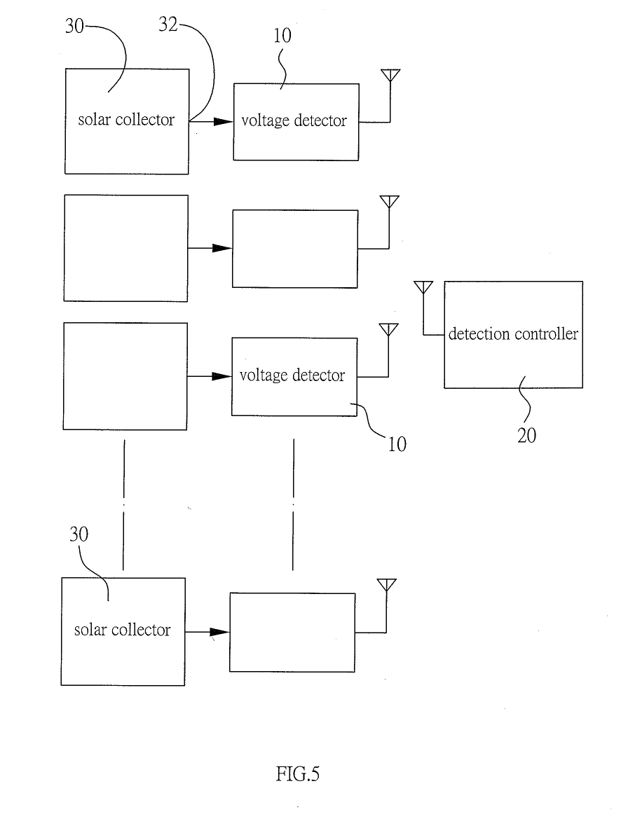

Referring to FIGS. 1-5, a detection device for a solar system in accordance with the preferred embodiment of the present invention comprises a plurality of solar collectors 30, a plurality of voltage detectors 10 each connected to a respective one of the solar collectors 30, and a detection controller 20 connected to each of the voltage detectors 10.

The solar collectors 30 are connected serially with each other. Each of the solar collectors 30 has a power output terminal 32. Each of the solar collectors 30 has a back face provided with a receiving box 31.

Each of the voltage detectors 10 is mounted in the receiving box 31 of the respective solar collector 30. Each of the voltage detectors 10 includes a voltage detection circuit 11 connected to the respective solar collector 30 and a wireless transmitting circuit 12 connected to the voltage detection circuit 11. The voltage detection circuit 11 of each of the voltage detectors 10 is connected in parallel with the power output terminal 32 of the respective solar collector 30 to detect an output voltage of the respective solar collector 30 and to form a voltage signal of the respective solar collector 30. The wireless transmitting circuit 12 of each of the voltage detectors 10 receives the voltage signal of the respective solar collector 30 from the voltage detection circuit 11 and transmits the voltage signal of the respective solar collector 30 to the detection controller 20 in a wireless manner.

The detection controller 20 includes a wireless receiving circuit 22 connected to the wireless transmitting circuit 12 of each of the voltage detectors 10 and a detection control circuit 21 connected to the wireless receiving circuit 22. The wireless receiving circuit 22 of the detection controller 20 receives the voltage signals of the solar collectors 30 from the wireless transmitting circuit 12 of each of the voltage detectors 10. The detection control circuit 21 of the detection controller 20 checks the voltage signals of the solar collectors 30 from the wireless receiving circuit 22 to compare a difference between the voltage signals of the solar collectors 30 so as to judge if the solar collectors 30 are disposed at a normal generating condition.

When in use, the voltage detection circuit 11 of each of the voltage detectors 10 can detect the output voltage of each of the solar collectors 30 successively to form a voltage signal of each of the solar collectors 30. Then, the wireless transmitting circuit 12 of each of the voltage detectors 10 receives the voltage signal of each of the solar collectors 30 from the voltage detection circuit 11 and transmits the voltage signal of each of the solar collectors 30 to the detection controller 20 in a wireless manner. Then, the wireless receiving circuit 22 of the detection controller 20 receives the voltage signals of the solar collectors 30 from the wireless transmitting circuit 12 of each of the voltage detectors 10. Then, the detection control circuit 21 of the detection controller 20 checks the voltage signals of the solar collectors 30 from the wireless receiving circuit 22 to compare the difference between the voltage signals of the solar collectors 30 so as to judge if the solar collectors 30 are disposed at a normal generating condition.

In practice, when the solar collectors 30 are worked at the normal condition, the voltage signals of all of the solar collectors 30 will have the same voltage value with a determined error. On the contrary, when one of the solar collectors 30 is worked at an abnormal condition, for example, when one of the solar collectors 30 is contaminated or inoperative, the voltage signal of one of the solar collectors 30 has a voltage value different from (usually smaller than) that of the voltage signals of other solar collectors 30. Thus, when the detection control circuit 21 of the detection controller 20 detects that the voltage signal of one of the solar collectors 30 has a voltage value different from that of the voltage signals of other solar collectors 30, the detection control circuit 21 of the detection controller 20 emits a signal to inform the operator that one of the solar collectors 30 is worked at an abnormal condition, so that the operator can clean or repair the abnormal solar collector 30 easily and quickly.

Accordingly, the voltage detectors 10 can detect the output voltages of the solar collectors 30, and the detection controller 20 can compare the difference between the output voltages of the solar collectors 30 so as to judge if the solar collectors 30 are disposed at a normal operation condition, thereby facilitating maintenance of the solar collectors 30. In addition, when the detection controller 20 detects that the voltage of one of the solar collectors 30 is different from that of other solar collectors 30, the detection controller 20 emits a signal to inform the operator that one of the solar collectors 30 is worked at an abnormal condition, so that the operator can clean or repair the abnormal solar collector 30 easily and quickly.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the true scope of the invention.

1. A detection device, comprising:
a plurality of solar collectors;
a plurality of voltage detectors each connected to a respective one of the solar collectors; and
a detection controller connected to each of the voltage detectors;
wherein each of the voltage detectors includes:
a voltage detection circuit connected to the respective solar collector; and
a wireless transmitting circuit connected to the voltage detection circuit;
the detection controller includes:
a wireless receiving circuit connected to the wireless transmitting circuit of each of the voltage detectors; and
a detection control circuit connected to the wireless receiving circuit.

2. The detection device of claim 1, wherein
each of the solar collectors has a power output terminal;
the voltage detection circuit of each of the voltage detectors is connected in parallel with the power output terminal of the respective solar collector.

3. The detection device of claim 2, wherein
the voltage detection circuit of each of the voltage detectors detects an output voltage of the respective solar collector and forms a voltage signal of the respective solar collector;
the wireless transmitting circuit of each of the voltage detectors receives the voltage signal of the respective solar collector from the voltage detection circuit and transmits the voltage signal of the respective solar collector to the detection controller in a wireless manner;
the wireless receiving circuit of the detection controller receives the voltage signals of the solar collectors from the wireless transmitting circuit of each of the voltage detectors;
the detection control circuit of the detection controller checks the voltage signals of the solar collectors from the wireless receiving circuit to compare a difference between the voltage signals of the solar collectors so as to judge if the solar collectors are disposed at a normal generating condition.

4. The detection device of claim 1, wherein
each of the solar collectors has a back face provided with a receiving box;
each of the voltage detectors is mounted in the receiving box of the respective solar collector.

5. The detection device of claim 1, wherein the solar collectors are connected serially with each other.
